(19) United States
(12) Patent Application Publication
(10) Pub. No.: US 2008/0185600 A1
(43) Pub. Date: Aug. 7, 2008

(54) Phosphor particles with plural coatings for LEDs

(75) Inventor: Alan C. Thomas, Gilbert, AZ (US)

Correspondence Address: Paul F. Wille;Cantor Colburn LLP, 55 Griffin Road South, Bloomfield, CT, 06002, US

(73) Assignee: World Properties, Inc., Lincolnwood, IL (US)

(21) Appl. No.: 11/701,987

(22) Filed: Feb. 2, 2007

(51) Int. Cl. H01L 33/00

(52) U.S. Cl. 257/98; 257/E33.061

(57) ABSTRACT

A light emitting semiconductor device including a light emitting diode having a cascading phosphor is improved by the particles of phosphor being coated with a moisture barrier layer and a buffer layer. Either the buffer layer overlies the moisture barrier layer or the moisture barrier layer overlies the buffer layer. In the latter case, the particles can further include a buffer layer over the moisture barrier layer. Preferred materials for the buffer layer are silica or alumina, which can include other oxides in the layer.

### BACKGROUND OF THE INVENTION

This invention relates to the treatment of particles of phosphor for light emitting diodes (LEDs) and, in particular, to phosphor particles with plural coatings to improve durability without impairing brightness.

A light emitting diode emits light substantially at a single wavelength. The purity of color is useful in some applications, e.g. in brake lights for vehicles, but a device emitting substantially white light is more generally useful. White light is a mixture of a plurality of wavelengths, although light can appear white even if a continuous spectrum of colors is not present. It has long been known in the art to add phosphorescent or fluorescent materials to the package of an LED to convert some of the light generated by the LED into another color; e.g. see U.S. Pat. No. 3,510,732 (Amans). The process is known as cascade; e.g. see U.S. Pat. No. 2,476,619 (Nicoll). In order to produce light at a different color, some light must be absorbed, reducing brightness. Thus, the quest for both improved color and increased brightness continues, e.g. see U.S. Pat. No. 7,157,746 (Ota et al.), and a host of phosphors have been proposed for this purpose.

As used herein, a phosphor is a material that produces light when stimulated by an electric field or by absorbing light. In the prior art, the term “dye” is sometimes used (incorrectly) for materials that emit light. This invention does not concern dye, by which is meant a material that absorbs (subtracts) light at selected wavelengths to provide a desired color but does not produce light.

Phosphors for LEDs must survive the environment during manufacture and then must survive contact with moisture and intense radiation from the light emitting chip during operation. In many cases, reactive epoxy or silicone resins are used to encapsulate the chip and are in intimate contact with the phosphor particles.

It is known in the art relating to thick film, electroluminescent (EL) lamps to encapsulate phosphors with a moisture resistant coating to improve the performance of the phosphor. For example, U.S. Pat. No. 5,418,062 (Budd) discloses zinc sulfide phosphors for use in the manufacture of EL panels wherein the phosphor particles include a transparent coating of metal oxide.

It is known in the art to coat phosphor for a fluorescent lamp with alumina (Al₂O₃) by oxidizing trimethyl aluminum (Al(CH₃)₃ -TMA), in a fluidized bed; see U.S. Pat. No. 4,585,673 (Sigai). It is also known in the art to form a thin coating of alumina derived from hydrolyzed trimethyl aluminum (TMA) on the surface of each particle of phosphor to protect the particle from moisture; e.g. see U.S. Pat. No. 5,080,928 (Klinedinst). The coating is produced by treating the particles in a fluidized bed. TMA is vaporized in an inert carrier gas and water is vaporized in an inert carrier gas. The two carrier gases are passed through the fluidized bed and the TMA reacts with the water to form a coating of alumina.

Phosphor is sensitive material. Initial luminance, life (time to half brightness), color, and other parameters are all easily affected by the manner in which the phosphor is treated, whether the treatment be physical, chemical, or electrical. It is extremely difficult to improve one parameter of a phosphor without causing other parameters to deteriorate, often significantly.

One cannot predict that coatings suitable for phosphors used in EL lamps will be suitable on phosphors used with LEDs. It has been found that some resins containing phosphor are discolored or damaged by a reaction with a titania component of the coating on the phosphor. The life of the LED is reduced. It has also been found that a supposedly protective coating can react with a phosphor, ruining it. For example, U.S. Pat. No. 5,958,591 (Budd) discloses plural coatings on one type of EL phosphor (Sylvania 729), wherein the initial coating is alumina derived from TMA. The TMA reacts with STG phosphor, described herein, making the phosphor turn dark gray and unusable. This situation is not contemplated in the Budd patent.

In view of the foregoing, it is therefore an object of the invention to improve the life of diodes emitting white light, in particular, or, more generally, light emitting diodes having a cascading phosphor.

Another object of the invention is to protect the cascading phosphor on light emitting diodes from unwanted chemical reactions, whether arising from the presence of other substances or from actinic radiation.

### SUMMARY OF THE INVENTION

The foregoing objects are achieved in this invention in which it has been found that a buffer layer, which may not be a moisture barrier, is a barrier to LED encapsulants and protects phosphor from damage caused by either a moisture barrier or the precursors for depositing the moisture barrier. Preferred compositions for the buffer layer are silica and alumina, which can include other oxides in the layer.

### BRIEF DESCRIPTION OF THE DRAWINGS

A more complete understanding of the invention can be obtained by considering the following detailed description in conjunction with the accompanying drawings, in which:

FIG. 1 is a chart illustrating a process in accordance with a first aspect of the invention;

FIG. 2 is a chart illustrating a process in accordance with a second aspect of the invention;

FIG. 3 is a diagram illustrating apparatus for performing a process in accordance with the invention; and

FIG. 4 is a chart of test results from several coating trials.

### DETAlLED DESCRIPTION OF THE INVENTION

In the following detailed description, particular phosphors are identified. These are phosphors currently in favor, generically known as rare earth phosphors because they contain elements from the rare earth group in the periodic table. For example, U.S. Pat. Nos. 6,252,254 (Soules et al.) and 6,544,438 (Yocom et al.) disclose such phosphors. The invention is not limited to phosphors currently in favor but applies to any phosphor that reacts with other materials and must be coated. For example, CaS:Eu is a deep red phosphor that reacts strongly with water to produce calcium hydroxide and hydrogen sulfide. In other words, the problem is the phosphor and the solution is the invention, which applies to any phosphor exhibiting the problem.

In the following description, “SCS” refers to the phosphor CaSrS:Eu and “STG” refers to the phosphor SrGa₂S₄:Eu. SCS is an orange-red phosphor and STG is a yellow-green phosphor. Both phosphors are extremely sensitive to water and both phosphors will react with other materials.

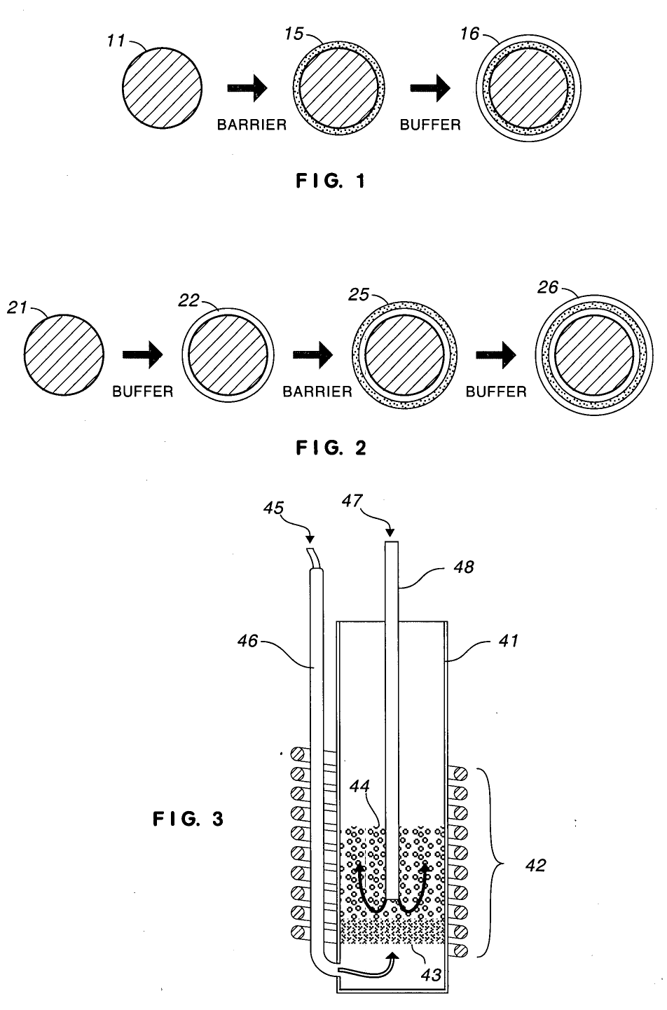

In FIG. 1, in accordance with the invention, phosphor particle 11 is first coated with layer 15, which is a moisture barrier for protecting phosphor particle 11. The coated particle is then coated with buffer layer 16, which protects the phosphor and the moisture barrier from coming into contact with encapsulating resins and the like. Each layer substantially covers the particle. In the following table, “(Si/Ti)O₂” represents a mixture of silica and titania. Preferred combinations of materials for the layers are listed in the following table.

| | | | |
|---|---|---|---|
| Layer 15 | SiO₂ | (Si/Ti)O₂ | (Si/Ti)O₂ |
| Layer 16 | Al₂O₃ | SiO₂ | Al₂O₃ |

Some moisture barriers degrade the performance of the underlying phosphor; e.g. brightness, life, or both. In accordance with the invention, as illustrated in FIG. 2, there is a buffer between the moisture barrier and the phosphor. Specifically, phosphor particle 21 is coated with buffer layer 22, then coated with moisture barrier 25, and is then coated with buffer layer 26. Preferred combinations of materials for the layers are listed in the following table. The third (middle) column is preferred among the combinations listed.

| | | | | |
|---|---|---|---|---|
| Layer 22 | SiO₂ | SiO₂ | Al₂O₃ | Al₂O₃ |
| Layer 25 | (Si/Ti)O₂ | (Si/Ti)O₂ | (Si/Ti)O₂ | (Si/Ti)O₂ |
| Layer 26 | SiO₂ | Al₂O₃ | SiO₂ | Al₂O₃ |

The coatings are preferably applied in a fluidized bed reactor, which provides complete coverage of the particles. A suitable reactor is schematically illustrated in FIG. 3. Glass reactor tube 41 is surrounded at the lower end by heater 42. Inside tube 41, porous glass frit 43 supports charge 44 of phosphor particles. Gas mixture 45, containing nitrogen and water vapor, is coupled to tube 46, wherein it is warmed and flows upwardly through phosphor particles 44, fluidizing the charge. Reactant gas mixture 47 flows downwardly through tube 48 and is released at the lower end of the fluidized bed of phosphor particles. Gas mixture 47 reacts with water vapor at the surface of the phosphor particles, forming a coating.

A specific procedure for implementing the invention is provided in the following examples.

### EXAMPLE 1

A 80 mm diameter fritted disk glass tube reactor, approximately 45 cm long was heated to 225° C. using a heating jacket. The injection of nitrogen gas through the porous glass frit was controlled with a flow meter. A charge of 300 g of SCS type LED phosphor was added to the top of the frit and flow of nitrogen was set to 2.1 L/min through the bottom of the frit. The phosphor temperature was measured and brought to equilibrium at 210° C. with the heating jacket. A metal injector tube was placed into the phosphor fluidized bed. Nitrogen flowing through the tube purged the injector. Water vapor was added to the fluidizing gas. Then TiCl₄, at 0.76 L/min, and SiCl₄, at 0.19 L/min, were started through gas bubblers and combined as the reactant gas mixture. The reaction continued for eight hours. The flows of reactants were stopped and the reactor was purged with pure nitrogen.

### EXAMPLE 2

A 40 mm diameter fritted disk glass tube reactor, approximately 40 cm long was heated to 225° C. using a heating jacket. Nitrogen gas injection through the porous glass frit was controlled with a flow meter. A charge of 70 g of previously-coated SCS type LED phosphor was added to the top of the frit and flow of nitrogen was set to 0.77 L/min through the bottom of the frit. A reactant gas mixture of Si(OCH₃)₄ at 0.12 L/min was then provided. The flows continued for six hours. The reactor was purged and the flows and heating stopped. The treated phosphor particles were cooled and removed.

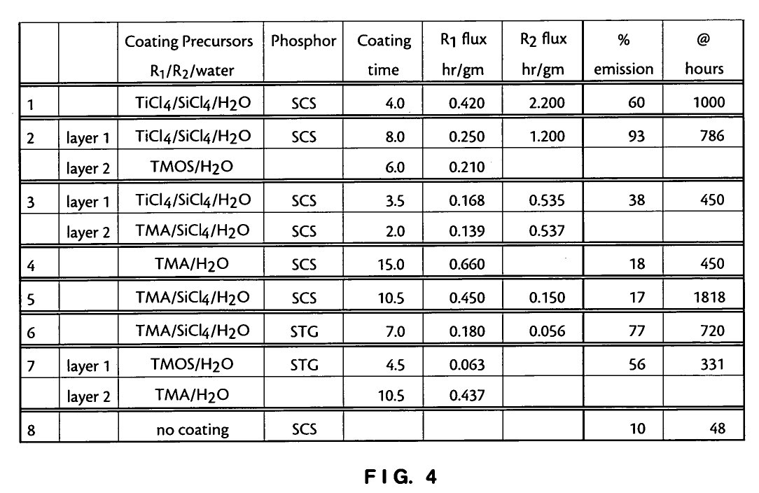

The phosphor was tested by measuring the emission under UV radiation before and after exposure to an environment of 85° C. and 85% relative humidity. FIG. 4 is a chart of the results of the tests of several batches of treated phosphor. Sample number 2, specifically described above, significantly improved protection over no coating.

The invention thus improves the life of light emitting diodes having a cascading phosphor. The coatings protect the cascading phosphor on light emitting diodes from unwanted chemical reactions, whether arising from the presence of other substances or from actinic radiation.

Having thus described the invention, it will be apparent to those of skill in the art that various modifications can be made within the scope of the invention. For example, the flows and temperatures are by way of example only and are readily determined empirically for a particular combination of phosphor and coating. Other oxides can be deposited, such as ZnO from the reaction of Zn(C₂H₅)₂ with water. Suitable silicon bearing precursors include Si(OCH₃)₄, Si(OC₂H₅)₄, and SiCl₄,. Triethylaluminum (TEA) can be used in place of TMA. The invention can be used with any phosphor coated, light emitting diode, e.g. gallium arsenide or other semiconductive material, surface emitters or edge emitters.

What is claimed is:

1. A light emitting semiconductor device including a light emitting diode having a coating containing at least one phosphor characterized in that the particles of phosphor include a moisture barrier layer and a buffer layer.

2. The light emitting semiconductor device as set forth in claim 1 wherein the buffer layer overlies the moisture barrier layer.

3. The light emitting semiconductor device as set forth in claim 1 wherein the moisture barrier layer overlies the buffer layer.

4. The light emitting semiconductor device as set forth in claim 3 and further including a buffer layer over the moisture barrier layer.

5. The light emitting semiconductor device as set forth in claim 1 wherein the buffer layer is selected from the group consisting of silica and alumina.
